(19) United States
(12) Patent Application Publication
(10) Pub. No.: US 2022/0223460 A1
(43) Pub. Date: Jul. 14, 2022

(54) TRANSFERRING APPARATUS AND METHOD FOR TRANSFERRING ELECTRONIC COMPONENT

(71) Applicant: ASTI GLOBAL INC., TAIWAN, Taichung City (TW)

(72) Inventor: Sheng Che Huang, Taichung City (TW)

(73) Assignee: ASTI GLOBAL INC., TAIWAN, Taichung City (TW)

(21) Appl. No.: 17/505,633

(22) Filed: Oct. 20, 2021

(30) Foreign Application Priority Data
Jan. 8, 2021 (TW) 110100848

(51) Int. Cl. H01L 21/683; H01L 21/68

(52) U.S. Cl. CPC H01L 21/6838; H01L 21/68

(57) ABSTRACT

A transferring apparatus configured to transfer a plurality of electronic components on a carrier film to a substrate. The transferring apparatus includes a controller and an abutting module. The abutting module is electrically connected to the controller, and includes an abutting element and a negative pressure generating device. The controller is configured to control the abutting element to move towards the substrate so as to abut the carrier film but not to penetrate through the carrier film, whereby the abutting element pushes the carrier film so as to push at least one of the electronic components to the substrate. The controller is configured to control the negative pressure generating device to suck air towards a direction opposite to a direction of the abutting element pushing the carrier film, so as to generate negative pressure to suck the carrier film. A method for transferring an electronic component is also provided.

### CROSS-REFERENCE TO RELATED APPLICATION

This application claims the priority benefit of Taiwanese application no. 110100848, filed on Jan. 8, 2021. The entirety of the above-mentioned patent application is hereby incorporated by reference herein and made a part of this specification.

### BACKGROUND

### Technical Field

The disclosure relates to a transferring apparatus and a method for transferring an electronic component.

### Description of Related Art

In the manufacturing process of electronic devices, generally speaking, it is a complicated process to transfer multiple electronic components to substrates or panels of different sizes to be applied. For example, it takes a lot of time for a robotic arm to sequentially transfer these electronic components from one substrate or panel to another. Therefore, the conventional apparatuses and methods for transferring electronic components encounter the problem of consuming a lot of time for transfer, which results in a lengthy manufacturing process and low efficiency.

Therefore, it is an important issue in the technical field of the disclosure to find out how to improve the transfer efficiency of electronic component through the design of process framework and the improvement of process flow.

### SUMMARY

The disclosure provides a transferring apparatus, which can efficiently transfer an electronic component to shorten the working time.

The disclosure provides a method for transferring an electronic component, which can efficiently transfer an electronic component to shorten the working time.

An embodiment of the disclosure provides a transferring apparatus. The transferring apparatus is configured to transfer a plurality of electronic components on a carrier film to a substrate. The transferring apparatus includes a controller and an abutting module. The abutting module is electrically connected to the controller, and includes an abutting element and a negative pressure generating device. The carrier film is placed between the substrate and the abutting module, and the carrier film is located between the electronic components and the abutting module. The controller is configured to control the abutting element to move towards the substrate so as to abut the carrier film but not to penetrate through the carrier film, whereby the abutting element pushes the carrier film so as to push at least one of the electronic components to the substrate. The controller is configured to control the negative pressure generating device to suck air towards a direction opposite to a direction along which the abutting element pushes the carrier film, so as to generate negative pressure to suck the carrier film.

An embodiment of the disclosure provides a method for transferring an electronic component, which includes: providing a carrier film on which an electronic component is arranged; providing a substrate; arranging the carrier film and the substrate to be opposite to each other, and making the substrate face a surface of the carrier film with the electronic component; providing an abutting element, so that the abutting element pushes the surface of the carrier film where the electronic component is not provided, such that the electronic component moves towards the substrate and contacts the substrate; and sucking air towards a direction opposite to a direction along which the electronic component moves, so that the carrier film is separated from the electronic component and the electronic component is transferred to the substrate.

In the transferring apparatus and the method for transferring the electronic component of the embodiment of the disclosure, the abutting element is used to push the carrier film to push the electronic component to the substrate, or the abutting element is pushed against the surface of the carrier film where the electronic component is not provided, so that the electronic component moves towards the substrate and contacts the substrate. Therefore, the electronic component can be transferred to the substrate in a more efficient manner, thereby shortening the working time. In addition, by sucking air in the direction opposite to the direction along which the abutting element pushes the carrier film, or sucking air in the direction opposite to the direction along with the electronic component moves, it is possible to facilitate the carrier film to be separated from the electronic component, and the working time can be further effectively shortened.

### BRIEF DESCRIPTION OF THE DRAWINGS

FIG. 1A to FIG. 1C are schematic cross-sectional views illustrating the flow of a method for transferring an electronic component by a transferring apparatus according to an embodiment of the disclosure.

FIG. 2 is a schematic cross-sectional view of a step of a method for transferring an electronic component by a transferring apparatus according to another embodiment of the disclosure.

FIG. 3 is a schematic cross-sectional view of a step of a method for transferring an electronic component by a transferring apparatus according to yet another embodiment of the disclosure.

FIG. 4 is a schematic cross-sectional view of a transferring apparatus according to still another embodiment of the disclosure.

FIG. 5 is a schematic cross-sectional view of a transferring apparatus according to another embodiment of the disclosure.

FIG. 6 is a flowchart of a method for transferring an electronic component according to an embodiment of the disclosure.

### DESCRIPTION OF THE EMBODIMENTS

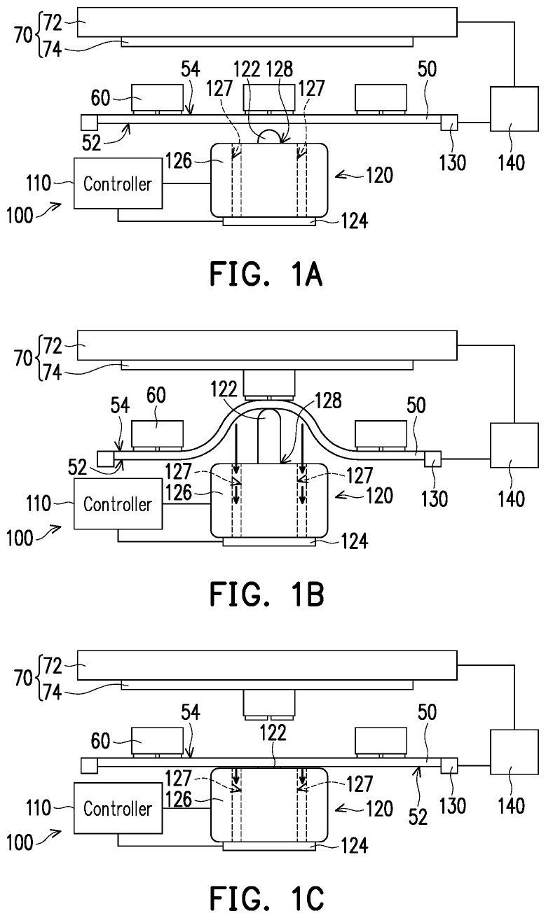

FIG. 1A to FIG. 1C are schematic cross-sectional views illustrating the flow of a method for transferring an electronic component by a transferring apparatus according to an embodiment of the disclosure. Referring to FIG. 1A and FIG. 1C, a transferring apparatus 100 of this embodiment is configured to transfer a plurality of electronic component 60 on a carrier film 50 to a substrate 70. In this embodiment, the carrier film 50 is a plastic film, such as a blue polyvinyl chloride (PVC) film, commonly known as a blue film, but the disclosure is not limited thereto. In addition, in this embodiment, the electronic component 60 is a chip or other electronic component, and the chip is, for example, a light-emitting diode chip, an integrated circuit chip, or other chips. The substrate 70 may include a carrier 72 and an adhesive tape 74 disposed on the carrier 72. The carrier 72 may be a glass carrier, a metal carrier, a semiconductor carrier, a plastic carrier, or made of other materials. In other embodiments, the substrate 70 can also be an adhesive carrier 72, for example, a carrier coated with an adhesive on the surface, and the surface needs not be provided with the adhesive tape 74.

The transferring apparatus 100 includes a controller 110 and an abutting module 120. The abutting module 120 is electrically connected to the controller 110 and includes an abutting element 122 and a negative pressure generating device 124. Specifically, the controller 110 may be electrically connected to an actuator for actuating the abutting element 122 and electrically connected to a negative pressure generating device. The carrier film 50 is placed between the substrate 70 and the abutting module 120, and the carrier film 50 is placed between the electronic components 60 and the abutting module 120. The controller 110 is configured to control the abutting element 122 to move towards the substrate 70 so as to abut the carrier film 50 but not to penetrate through the carrier film 50, whereby the abutting element 122 pushes the carrier film 50 to push at least one of the electronic components 60 (for example, an electronic component 60 in the figure) to the substrate 70, as in the process shown in FIG. 1A to FIG. 1B. In this embodiment, both the carrier film 50 and the substrate 70 have viscosity, and the viscosity of the substrate 70 to the electronic component 60 (for example, the viscosity of the adhesive tape 74 to the electronic component 60) is greater than the viscosity of the carrier film 50 to the electronic component 60. Therefore, when the abutting element 122 pushes the electronic component 60 to the substrate 70 and then returns to its original position, the strong viscosity of the substrate 70 will cause the electronic component 60 to retain on the substrate 70, and the carrier film 50 is separated from the electronic component 60. In this embodiment, the abutting element 122 is, for example, a pin needle, and the tip of the pin needle may be relatively smooth and round to avoid piercing the carrier film 50.

In addition, the controller 110 is configured to control the negative pressure generating device 124 to such air in a direction opposite to the direction along which the abutting element 122 pushes the carrier film 50 (that is, the downward direction in FIG. 1B in the embodiment, i.e., the direction facing away from the substrate 70), thereby generating negative pressure to suck the carrier film 50. In this way, it is possible to facilitate the carrier film 50 to be separated from the electronic component 60. In this embodiment, the negative pressure generating device 124 is a suction pump, a vacuum pump, or other devices that can generate negative pressure.

Specifically, in this embodiment, the controller 110 controls the negative pressure generating device 124 to start sucking air to generate negative pressure when the abutting element 122 pushes at least one of the electronic components 60 to the substrate 70. When the pushing is completed, the abutting element 122 returns to its original position, and then suction is stopped. In this way, when the abutting element 122 is pushed against the electronic component 60, the carrier film 50 located at the edge of the electronic component 60 can be sucked by the negative pressure generating device 124 first to separate from the electronic component 60, as shown in FIG. 1B. Afterwards, when the abutting element 122 moves in the direction of returning to its original position, the carrier film 50 located in the center of the electronic component 60 is then separated from the electronic component 60, as shown in the process of FIG. 1B to FIG. 1C. In this manner, it is possible to effectively prevent the carrier film 50 from deviating when separating from the electronic component 60, and the deviation will cause the position of the electronic component 60 to shift due to the uneven force applied to the electronic component 60.

In this embodiment, the abutting module 120 further includes a housing 126 with a plurality of suction openings 127, and the negative pressure generating device 124 sucks the carrier film 50 through the suction openings 127. In addition, in this embodiment, the housing 126 further includes a central opening 128, the suction openings 127 are provided beside the central opening 128, and the abutting element 122 is adapted to pass through the central opening 128 and move towards the substrate 70.

In addition, in this embodiment, the transferring apparatus 100 further includes a holder 130 and an actuator 140, and the holder 130 is configured to hold the carrier film 50. In this embodiment, the holder 130 is, for example, a fixing frame for fixing the carrier film 50. The actuator 140 is connected to at least one of the holder 130 and the abutting module 120 (in this embodiment, the actuator 140 is connected to the holder 130 as an example), and is configured to move the holder 130 along the extension direction of the carrier film 50 relative to the abutting module 120, that is, the horizontal movement in the figure. In this embodiment, the actuator 140 is further connected to the substrate 70, and the actuator 140 moves the carrier film 50 and the substrate 70 along the extension direction of the carrier film 50 relative to the abutting module 120. In this manner, after the abutting module 120 pushes one of the electronic components 60 to the substrate 70, the electronic components 60 at other positions on the carrier film 50 can be pushed to the substrate 70. In an embodiment, the actuator 140 may be connected to the substrate 70 through a holder, that is, the substrate 70 is fixed on the holder, and the actuator 140 moves the substrate 70 by moving the holder. In another embodiment, the actuator 140 can also be connected to the abutting module 120 to move the abutting module 120 along the extension direction of the carrier film 50 relative to the holder 130 by moving the abutting module 120, that is, to move the holder 130 along the extension direction of the carrier film 50 relative to the abutting module 120.

In the transferring apparatus 100 of this embodiment, the abutting element 122 is used to push the carrier film 50 to push the electronic component 60 to the substrate 70, or the abutting element 122 is pressed against the surface 52 of the carrier film 50 where the electronic component 60 is not provided (i.e., the lower surface in FIG. 1A to FIG. 1C), so that the electronic component 60 moves towards the substrate 70 and contacts the substrate 70. Therefore, the electronic component 60 can be transferred to the substrate 70 in a more efficient manner, thereby shortening the working time. For example, compared to using a robotic arm to transfer the electronic component 60, the method of pushing the electronic component 60 in this embodiment can indeed transfer the electronic component more efficiently, and can greatly shorten the working time. In addition, since the abutting element 122 does not penetrate through the carrier film 50 when the abutting element 122 is pushed against the electronic component 60, the stability of pushing the electronic component 60 to the substrate 70 can be increased, so that the electronic component 60 can be pushed to a correct position on the substrate 70 as expected.

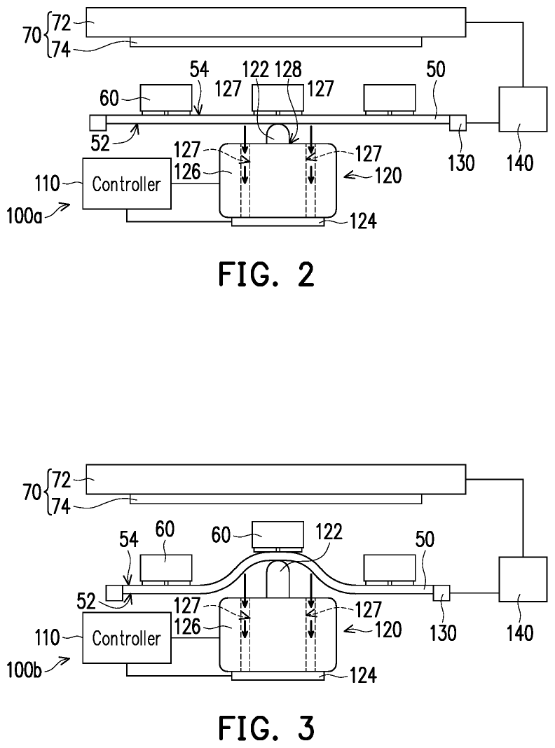

FIG. 2 is a schematic cross-sectional view of a step of a method for transferring an electronic component by a transferring apparatus according to another embodiment of the disclosure. Please refer to FIG. 2, the transferring apparatus 100a of this embodiment is similar to the transferring apparatus 100 of FIG. 1B, and the difference between the two is that the timing for the controller 110 to control the negative pressure generating device 124 to suck air is different. In the transferring apparatus 100a of this embodiment, the controller 110 controls the negative pressure generating device 124 to start sucking air to generate negative pressure when the abutting element 122 touches the carrier film 50 (as shown in FIG. 2). After the pushing is completed and the abutting element 122 returns to its original position, suction is stopped. In this manner, after the electronic component 60 is pushed to the substrate 70, it is possible to facilitate the carrier film 50 to be separated from the electronic component 60.

FIG. 3 is a schematic cross-sectional view of a step of a method for transferring an electronic component by a transferring apparatus according to yet another embodiment of the disclosure. Please refer to FIG. 3, the transferring apparatus 100b of this embodiment is similar to the transferring apparatus 100 of FIG. 1B, and the difference between the two is that the timing for the controller 110 to control the negative pressure generating device 124 to suck air is different. In the transferring apparatus 100b of this embodiment, the controller 110 controls the negative pressure generating device 124 to start sucking air to generate negative pressure after the abutting element 122 touches the carrier film 50 and before the abutting element 122 pushes at least one of the electronic components 60 to the substrate 70 (as shown in FIG. 3). After the pushing is completed and the abutting element 122 returns to its original position, suction is stopped. In this manner, after the electronic component 60 is pushed to the substrate 70, it is possible to facilitate the carrier film 50 to be separated from the electronic component 60.

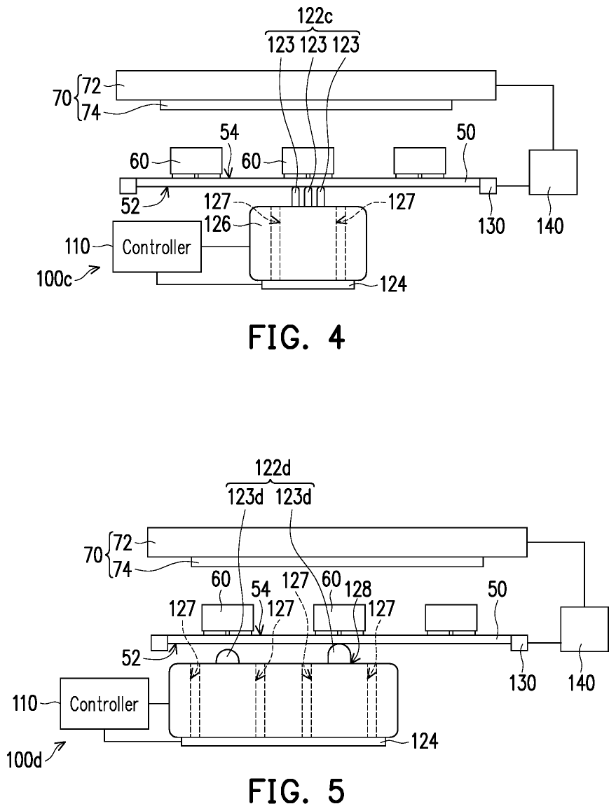

FIG. 4 is a schematic cross-sectional view of a transferring apparatus according to still another embodiment of the disclosure. Referring to FIG. 4, the transferring apparatus 100c of this embodiment is similar to the transferring apparatus 100 of FIG. 1A, and the difference between the two is as follows. In the transferring apparatus 100c of this embodiment, the abutting element 122c includes a plurality of pin needles 123, and these pin needles 123 are configured to push the same electronic component 60 at a time.

FIG. 5 is a schematic cross-sectional view of a transferring apparatus according to another embodiment of the disclosure. Referring to FIG. 5, the transferring apparatus 100d of this embodiment is similar to the transferring apparatus 100 of FIG. 1A, and the difference between the two is as follows. In the transferring apparatus 100d of this embodiment, the abutting element 122d includes a plurality of pin needles 123d for respectively pushing different electronic components 60. In this embodiment, the controller 110 is configured to separately control the actions of the pin needles 123d. For example, the pin needles 123d can be controlled to push a plurality of different electronic components 60 at different times and in a certain order.

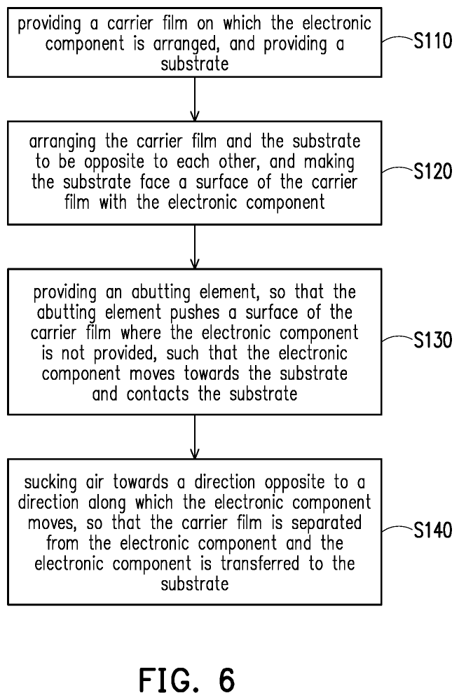

FIG. 6 is a flowchart of a method for transferring an electronic component according to an embodiment of the disclosure. Referring to FIG. 1A to FIG. 1C and FIG. 6, the method of transferring an electronic component in this embodiment can be implemented by using the transferring apparatus of the foregoing embodiments, and the transferring apparatus 100 of FIG. 1A to FIG. 1C is adopted as an example in the description below. In the method of transferring an electronic component of this embodiment, step S110 is performed first to provide the carrier film 50 on which the electronic component 60 is disposed. In addition, the substrate 70 is provided. Next, step S120 is performed to arrange the carrier film 50 and the substrate 70 to be opposite to each other, and the substrate 70 is arranged to face a surface 54 of the carrier film 50 with the electronic component 60, as shown in FIG. 1A. Thereafter, step S130 is performed to provide the abutting element 122, so that the abutting element 122 is pushed against the surface 52 of the carrier film 50 where the electronic component 60 is not provided, so as to move the electronic component 60 towards the substrate 70 and contact the substrate 70, as shown in FIG. 1B. Furthermore, step S140 is performed to suck air in a direction opposite to the direction along which the electronic component 60 moves, so that the carrier film 50 is separated from the electronic component 60, and the electronic component 60 is transferred to the substrate 70, as shown in FIG. 1C. For example, as described in the above embodiment, the strong viscosity of the substrate 70 can keep the electronic component 60 on the substrate 70, while the carrier film 50 that is less adhesive to the electronic component 60 will be separated from the electronic component 60. Step S140 may be performed after step S130, or may partially overlap with the time of performing step S130. For detailed time of performing the steps, please refer to the embodiments of FIG. 1A to FIG. 1C, the embodiment of FIG. 2 and the embodiment of FIG. 3, no further description is incorporated herein.

As described in the above embodiments of FIG. 1A to FIG. 1C, the method of transferring the electronic component of this embodiment can transfer the electronic component 60 to the substrate 70 in a more efficient manner, thereby shortening the working time.

The method of transferring the electronic component of this embodiment further includes the operation of making the abutting element 122 to abut the carrier film 50 but not to penetrate through the carrier film 50 when the abutting element 122 is pressed against the surface 52 of the carrier film 50 where the electronic component 60 is not provided so as to move the electronic component 60 towards the substrate 70. Moreover, the method of transferring an electronic component of this embodiment further includes the operation of pushing the abutting element 122 against another position on the surface 52 of the carrier film 50 where the electronic component 60 is not provided, so that another electronic component 60 moves towards the substrate 70 and contacts the substrate 70. Specifically, the actuator 140 can be used to move the carrier film 50 and the substrate 70 along the extension direction of the carrier film 50 relative to the abutting module 120, so that the abutting module 120 can be further pushed against the electronic components 60 at other positions on the carrier film 50 after pushing one of the electronic components 60 to the substrate 70. After repeatedly pushing and moving the carrier film 50, the electronic components 60 on the carrier film 50 can be pushed the substrate 70 in sequence.

Other details and changes of the method of transferring the electronic component of this embodiment are described thoroughly in the embodiments of FIG. 1A to FIG. 5, and no further description is incorporated herein.

In an embodiment, the controller 110 is, for example, a central processing unit (CPU), a microprocessor, a digital signal processor (DSP), a programmable controller, a programmable logic device (PLD) or other similar devices or a combinations of these devices, the disclosure provides no limitation thereto. Furthermore, in an embodiment, various functions of the controller 110 can be implemented as a plurality of program codes. These program codes are stored in a memory, and the controller 110 executes the program codes. Alternatively, in an embodiment, various functions of the controller 110 may be implemented as one or more circuits. The disclosure provides no limitation to the use of software or hardware to implement the functions of the controller 110.

To sum up, in the transferring apparatus and the method of transferring the electronic component of the embodiment of the disclosure, the abutting element is used to push the carrier film to push the electronic component to the substrate, or the abutting element is pushed against the surface of the carrier film where the electronic component is not provided, so as to move the electronic component towards the substrate and contact the substrate. Therefore, the electronic component can be transferred to the substrate in a more efficient manner, thereby shortening the working time. Additionally, by sucking air in the direction opposite to the direction along which the abutting element is pressed against the carrier film, or sucking air in the direction opposite to the direction along which the electronic component moves, it is possible to facilitate the carrier film to be separated from the electronic component, and the working time can be further effectively shortened.

What is claimed is:

1. A transferring apparatus, configured to transfer a plurality of electronic components on a carrier film to a substrate, comprising:
a controller; and
an abutting module electrically connected to the controller, and comprising an abutting element and a negative pressure generating device, wherein the carrier film is placed between the substrate and the abutting module, and the carrier film is located between the electronic components and the abutting module, the controller is configured to control the abutting element to move towards the substrate so as to abut the carrier film but not to penetrate through the carrier film, whereby the abutting element pushes the carrier film so as to push at least one of the electronic components to the substrate, the controller is configured to control the negative pressure generating device to suck air towards a direction opposite to a direction along which the abutting element pushes the carrier film, so as to generate a negative pressure to suck the carrier film.

2. The transferring apparatus according to claim 1, wherein the controller controls the negative pressure generating device to start sucking air to generate the negative pressure when the abutting element touches the carrier film, when the pushing is completed, the abutting element returns to its original position, and then suction is stopped.

3. The transferring apparatus according to claim 1, wherein the controller controls the negative pressure generating device to start sucking air to generate the negative pressure when the abutting element pushes the at least one of the electronic components to the substrate, when the pushing is completed, the abutting element returns to its original position, and then suction is stopped.

4. The transferring apparatus according to claim 1, wherein the controller controls the negative pressure generating device to start sucking air to generate the negative pressure after the abutting element touches the carrier film and before the abutting element pushes the at least one of the electronic components to the substrate, when the pushing is completed, the abutting element returns to its original position, and then suction is stopped.

5. The transferring apparatus according to claim 1, wherein the abutting element comprises a plurality of pin needles, and the pin needles are configured to push the same electronic component at a time.

6. The transferring apparatus according to claim 1, wherein the abutting element comprises a plurality of pin needles, and the pin needles are configured to push different electronic components.

7. The transferring apparatus according to claim 6, wherein the controller is configured to separately control actions of the pin needles.

8. The transferring apparatus according to claim 1, wherein the abutting module further comprises a housing with a plurality of suction openings, and the negative pressure generating device sucks the carrier film through the suction openings.

9. The transferring apparatus according to claim 8, wherein the housing further comprises a central opening, the suction openings are provided beside the central opening, and the abutting element is adapted to pass through the central opening and move towards the substrate.

10. The transferring apparatus according to claim 1, further comprising:
a holder, configured to hold the carrier film; and
an actuator, connected to at least one of the holder and the abutting module, and configured to move the holder along an extension direction of the carrier film relative to the abutting module.

11. A method for transferring an electronic component, comprising:
providing a carrier film on which the electronic component is arranged;
providing a substrate;
arranging the carrier film and the substrate to be opposite to each other, and making the substrate face a surface of the carrier film with the electronic component;
providing an abutting element, so that the abutting element pushes a surface of the carrier film where the electronic component is not provided, such that the electronic component moves towards the substrate and contacts the substrate; and
sucking air towards a direction opposite to a direction along which the electronic component moves, so that the carrier film is separated from the electronic component and the electronic component is transferred to the substrate.

12. The method for transferring the electronic component according to claim 11, further comprising:
when the abutting element is pushed against the surface of the carrier film where the electronic component is not provided so that the electronic component moves towards the substrate, making the abutting element to abut the carrier film but not to penetrate through the carrier film.

13. The method for transferring the electronic component according to claim 11, wherein the step of sucking air towards the direction opposite to the direction along which the electronic component moves comprises:
starting sucking air when the abutting element touches the carrier film, after the pushing is completed and the abutting element returns to its original position, stopping suction.

14. The method for transferring the electronic component according to claim 11, wherein the step of sucking air towards the direction opposite to the direction along which the electronic component moves comprises:
starting sucking air when the abutting element pushes the carrier film so as to make the electronic component touch the substrate, after the pushing is completed and the abutting element returns to its original position, stopping suction.

15. The method for transferring the electronic component according to claim 11, wherein the step of sucking air towards the direction opposite to the direction along which the electronic component moves comprises:
starting sucking air after the abutting element touches the carrier film and before the electronic component touches the substrate, after the pushing is completed and the abutting element returns to its original position, stopping suction.

16. The method for transferring the electronic component according to claim 11, wherein both the carrier film and the substrate have viscosity, and the viscosity of the substrate to the electronic component is greater than the viscosity of the carrier film to the electronic component.

17. The method for transferring the electronic component according to claim 11, wherein the abutting element comprises a plurality of pin needles, and the pin needles abut against a position of the same electronic component corresponding to the carrier film at a time.

18. The method for transferring the electronic component according to claim 11, wherein the abutting element comprises a plurality of pin needles, and the pin needles respectively abut against a plurality of different positions of a plurality of different electronic components corresponding to the carrier film.

19. The method for transferring the electronic component according to claim 18, further comprising making the pin needles to actuate respectively so as to abut against the different positions at different times.

20. The method for transferring the electronic component according to claim 11, further comprising providing a housing with a plurality of suction openings, and the step of sucking air towards the direction opposite to the direction along which the electronic component moves comprises sucking air to suck the carrier film through the suction openings.

21. The method for transferring the electronic component according to claim 20, wherein the housing further comprises a central opening, the suction openings are provided beside the central opening, and the abutting element is adapted to pass through the central opening and move towards the substrate to push the carrier film.

22. The method for transferring the electronic component according to claim 11, further comprising pushing the abutting element against another position on the surface of the carrier film where the electronic component is not provided, so that another electronic component moves towards the substrate and contacts the substrate.
